(19) United States
(12) Patent Application Publication
(10) Pub. No.: US 2015/0309125 A1
(43) Pub. Date: Oct. 29, 2015

(54) Monolithic Three-Axis Magnetometer

(71) Applicants: Yue Huang, East Lansing, MI (US); Jue Lu, Okemos, MI (US)

(72) Inventors: Yue Huang, East Lansing, MI (US); Jue Lu, Okemos, MI (US)

(73) Assignee: LABSYS LLC, East Lansing, MI (US)

(21) Appl. No.: 14/262,804

(22) Filed: Apr. 28, 2014

(51) Int. Cl. G01R 33/02; G01R 33/00

(52) U.S. Cl. CPC G01R 33/0206; G01R 33/0052

(57) ABSTRACT

A three-axis magnetic field sensing device, a magnetometer, and methods of fabricating and testing are presented. The magnetometer comprises a plurality of sloped surfaces. A plurality of magnetic sensing units is disposed on the slopes. A magnetic field can be measured by the sensing units. Each of the three orthogonal-axis components of the magnetic field, a Euclidean vector, can then be solved by using a simple algorithm as an expression of the sensing unit measurement values and slope angles. Polarization, testing and characterization of the device could be done by applying a magnetic field along a common axis to all sensing units, along which each sensing unit has sensitivity.

### CROSS-REFERENCE TO RELATED APPLICATIONS

This application claims an invention which was disclosed in Provisional Application No. 61/817,294, filed Apr. 29, 2013, entitled “A Monolithic Three-Axis Magnetometer.” The benefit under 35 USC §119(e) of the United States provisional application is hereby claimed, and the aforementioned application is hereby incorporated herein by reference.

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### FIELD OF INVENTION

The present invention is related to magnetic field sensor that provides three orthogonal axes sensing and the method for manufacturing the same in quantities.

### BACKGROUND

Miniaturized three-axis magnetic sensors that detect all three mutually orthogonal components of a magnetic field, X, Y and Z are integrated into GPS, and smart phones etc. to provide geometrical direction. Those sensors are mass produced extensively using microfabrication technology mostly on flat surfaces of silicon wafers. The wafers are then diced into individual sensor dies where each may contain only one or two sensitive directions. For example, previous arts (U.S. Pat. Nos. 7,536,909, 8,316,552 and 7,271,586) used at least one die to provide in-plane X and Y-axis sensing, and an additional die to provide Z-axis sensing, which has its sensitivity axis orthogonal to the former plane. There are monolithic solutions that contain all three axes sensors in one die, such as U.S. Pat. No. 8,390,283 B2 and Asahi Kasei Microsystem's AK8975. With aid of magnetic flux guides to coerce the magnetic field, out-of-plane field can be detected using in-plane sensing units. However, the out-of-plane field measurement accuracy of the coerced-field solutions is inferior to the multi-die solutions. The tradeoffs of multi-die solution are larger packaging size, greater complexity and higher cost. Unlike above coplanar approaches, another monolithic solution that balances accuracy and those tradeoffs is to tilt sensing units for out-of-plane field detection. Previous arts (U.S. Pat. Nos. 7,126,330, 7,358,722 B2 and U.S. Pat. Appln. No. 20120268113) place a number of sensing units on a flat surface of a rectangular block substrate to detect magnetic field components in X and/or Y direction, and sensing units on two slopes of a ditch in the substrate away from the X and Y sensors for Z component detection and decomposition.

### SUMMARY OF THE INVENTION

The current invention presents a monolithic three-axis magnetometer and methods of manufacturing, testing and calculation. The device presented in this invention places a plural of magnetic field sensing units for all three axes entirely on slopes. In a preferred embodiment, a square pyramid is formed out of silicon substrate, and four identical sensing units are positioned on each of the four trapezoid slopes of the pyramid. Any spatial magnetic field vector is directly projected and precisely measured by these four mutually tilted sensing units and then decomposed into three designated, mutually orthogonal axes using a simple algorithm. Microfabrication steps of the exemplary devices may include wet and dry etching, thin film deposition, photolithography, etc., and integrated with microelectromechanical systems (MEMS) and integrated circuits (IC) fabrication processes. The pinning and testing of exemplary sensors can be done by applying only Z-axis field.

### BRIEF DESCRIPTION OF THE DRAWINGS

FIG. 1A illustrates a perspective view of a first exemplary embodiment;

FIG. 1B illustrates a perspective view of a second exemplary embodiment;

FIG. 1C illustrates a perspective view of a third exemplary embodiment;

FIG. 1D illustrates a perspective view of a fourth exemplary embodiment;

FIG. 2A illustrates a top view of the first exemplary embodiment;

FIG. 2B illustrates a top view of the third exemplary embodiment;

FIG. 3A illustrates the cross-section view (the XZ plane) of the first embodiment;

FIG. 3B illustrates the cross-section view (the YZ plane) of the first embodiment;

FIG. 4A illustrates the relationships of H_{XZ}, the projection of an arbitrary field vector H on XZ plane, its projections Ha on sensitivity axis aa′ on slope 110 (left) and H_{b} on sensitivity axis bb′ on slope 120 (right) defined in FIG. 3A, and decomposition to H_{X} and H_{Z} along X and Z axes of the first embodiment of the present invention;

FIG. 4B illustrates the relationships of H_{YZ}, the projection of an arbitrary field vector H, its projections H, on sensitivity axis cc′ on slope 130 (left) and H_{d} on sensitivity axis dd′ on slope 140 (right) defined in FIG. 3B, and decomposition to H_{Y} and H_{Z} along Y and Z axes of the first embodiment of the present invention;

FIG. 5A illustrates the electrical schematic of a Wheatstone resistor bridge of an exemplary embodiment;

FIG. 5B illustrates an exemplary interconnection layout scheme of the resistors on the slope of the first exemplary embodiment;

FIG. 6A illustrates a microfabrication process flow of the first exemplary embodiment;

FIG. 6B illustrates a microfabrication process flow of the second exemplary embodiment;

FIG. 7 illustrates biasing all of the magnetic field sensing units of the first exemplary embodiment by applying a Z-axis field.

### DETAILED DESCRIPTION OF THE INVENTION

The following description is merely exemplary in nature and is not intended to limit the invention or its application and uses of the invention. Furthermore, there is no intention to be bound by any theory presented in the preceding background or the following description.

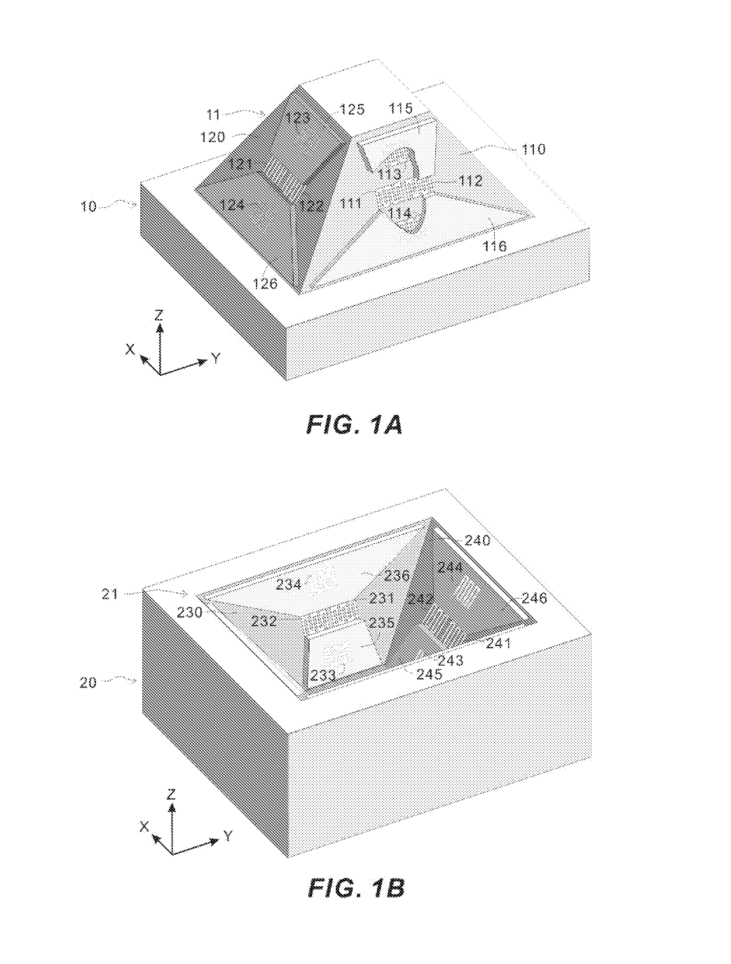

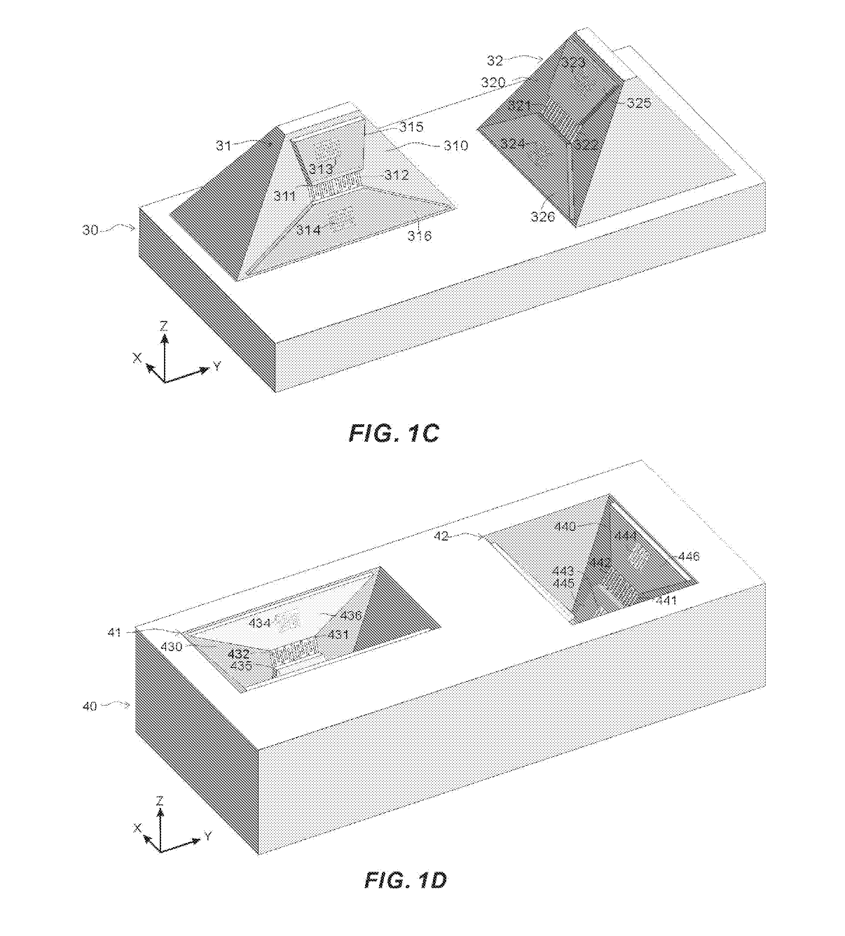

Referring now to the 3-axis magnetic field measurement device in more detail, four exemplary types of embodiments are presented: a convex square pyramid, a concave square pyramid, a pair of convex rectangular pyramid, and a pair of concave rectangular pyramids. The first exemplary type of embodiment is presented in FIG. 1A showing a convex square pyramid 11 on substrate 10. FIG. 1B shows the second type embodiment, a concave square pyramid 21 in substrate 20; FIG. 1C shows the third exemplary type embodiment, a pair of convex rectangular pyramid 31 and 32 on substrate 30; FIG. 1D shows the fourth type embodiment, a pair of concave rectangular pyramid 41 and 42 in substrate 40. Those pyramids can be truncated into frustums to reduce the height of the device. Each type of embodiment contains at least four sensing units on the slope faces of the pyramids.

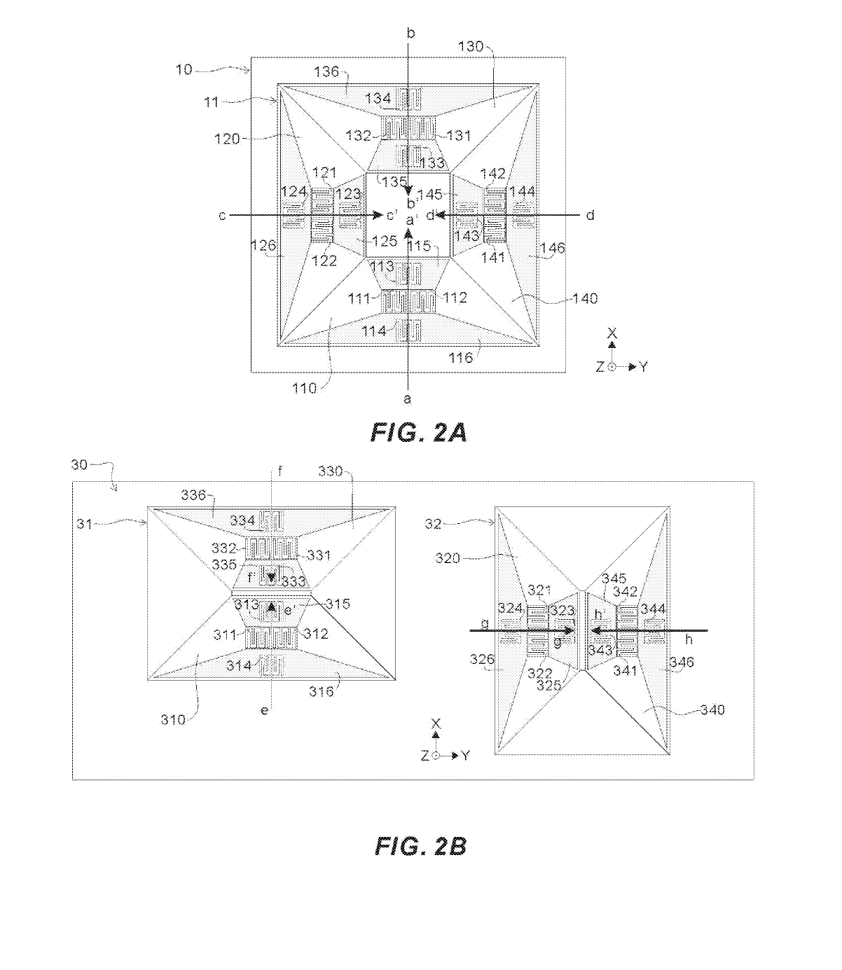

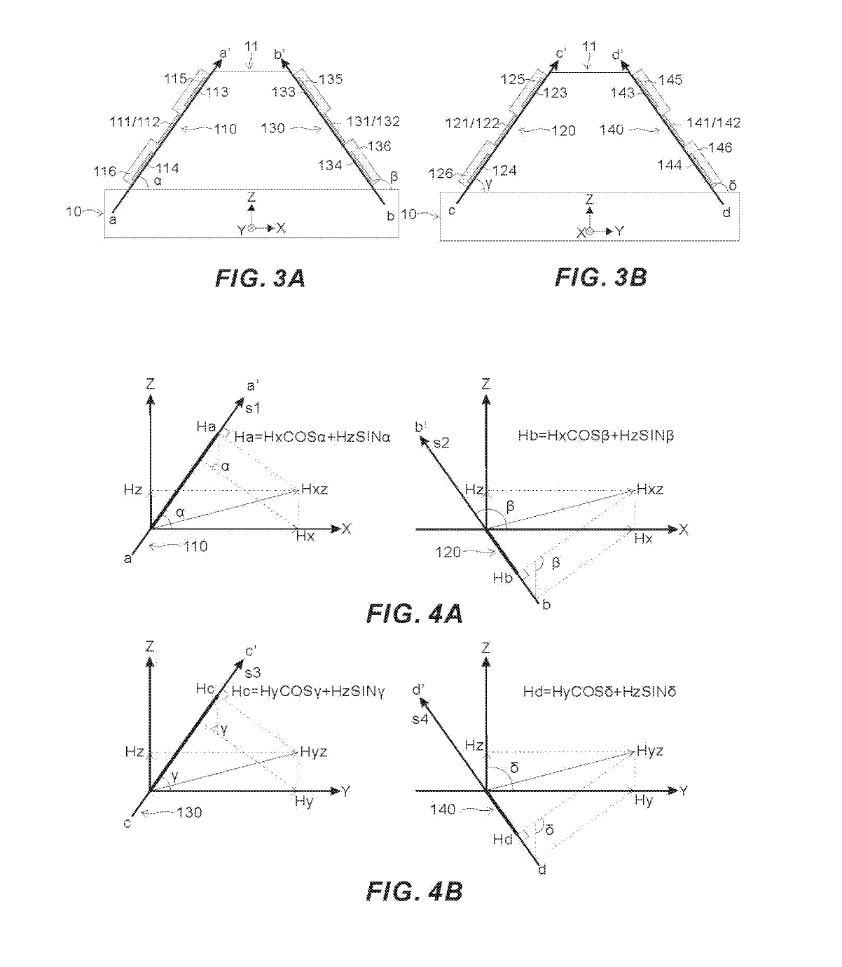

Referring now to the sensing units of the device in more detail, each sensing unit comprises of one or a plurality of sensing apparatus of, but not limited to, Hall effect or magnetoresistive sensing structures, electrical interconnections and magnetic flux concentrators. For exemplary magnetoresistive sensing structures as illustrated in FIG. 1A, four identical magnetoresistive resistors 110, 111, 112 and 113 on slope 110 are interconnected as a Wheatstone bridge. Two magnetoresistive resistors 111 and 112 are exposed in the gap between two flux concentrators 115 and 116, of which the resistances may change with applied magnetic field. The other two resistors 113 and 114 are shielded under 115 and 116, of which their resistances would not change with applied field. Please note the flux concentrators 115 and 116 are partially removed in the figure to reveal the underlying resistors 113 and 114. The sensitivity axis of a sensing unit is determined by its longitudinal direction of the unshielded magnetoresistive resistors, for examples, aa′ (the axis containing and in the same direction of the vector from point a to point a′) on slope 110 or ee′ on slope 310 as illustrated in FIG. 2A and FIG. 2B respectively. On slope 120, identical structures are constructed as on slope 110, as well as on the rest two slopes in the shade that are not shown in FIG. 1A, but otherwise shown in the device top view FIG. 2A and side views FIG. 3A and FIG. 3B. Two resistors 123 and 124 are desensitized to magnetic fields by shielding under 125 and 126 which are also function as flux concentrators, leaving resistors 121 and 122 exposed between 125 and 126. For another example, shielded resistor 233 and 234 in FIG. 1B are covered by flux concentrator 235 and 236 on slope 230. Unshielded resistor 231 and 232 are exposed between 235 and 236. Similarly, resistor 243 and 244 are covered by 245 and 246, shielding them. Resistors 241 and 242 are exposed between 245 and 246 allowing them to be affected by magnetic fields. FIG. 2A and FIG. 2B show the magnetoresistive resistors and flux concentrators on all four slopes of the first and third exemplary embodiment with convex pyramids respectively. The second exemplary embodiment has the same topography as the first exemplary embodiment viewing from the top. The sensitivity axes of the sensing units are coplanar with the isosceles trapezoid and in parallel with its altitude through the trapezoid center, labeled as aa′, bb′, cc′ and dd′ on slope 110, 130, 120 and 140, with tilt angles α and β with X-axis shown in FIG. 3A, and γ and δ with Y-axis shown in FIG. 3B respectively. Of the first embodiment, the XZ plane is designated as the virtue plane in which sensitivity axes aa′ and bb′ reside, and the YZ plane is designated as the virtue plane where cc′ and dd′ reside.

Further in a broad embodiment, the present invention is a three-axis magnetic field sensing device containing at least four tilted sensitivity axes, among which at least two sensitivity axes belong to or in parallel with one of the two orthogonal virtual planes. Each virtue plane or group of parallel virtue planes contains at least two sensing units with sensitivity axes of different directions. For the third exemplary embodiment illustrated in its projection view FIG. 1C and top view FIG. 2B, the sensing units may reside on different convex pyramids, 31 and 32. Further, the value obtained from a sensing unit remains if it is shifted in parallel if we assume the field across all sensing units is uniform. Thus, one sensitivity axis does not need to be in the same virtual plane with its companion sensitivity axis. For example, the sensitivity axes ee′ and ff′ illustrated in FIG. 2B may belong to two different however parallel virtual planes. The same is true for gg′ and hh′. Likewise, in the fourth exemplary embodiment, two of the sensing axes of different pyramid belong to two orthogonal virtual planes, and the other two sensing axes may each belong to or be parallel to the said virtual plane intercepting the same pyramid.

Referring now to the mathematical methods of this invention, a magnetic field H, a Euclidean vector, can be decomposed to a 3-tuple (H_{X}, H_{Y}, H_{Z}) by using its four projections, Hs1, Hs2, Hs3 and Hs4, on four sensing axes s1, s2, s3 and s4 respectively. The projections Hs1, Hs2, Hs3 and Hs4 are measurements of magnetic field vector H out of the four sensing units of the preferred embodiment, assuming that each sensing unit has the same sensitivity and experiences the same H. On the other hand, H can be projected onto two orthogonal planes XZ and YZ (denoted as H_{XZ} and H_{YZ} respectively). In the XZ plane as shown in FIG. 4A, if s1 and s2 denotes two axes with different angles (α and β) with respect to the X-axis, it can be proven that Hs1 and Hs2 (the projections of H_{XZ} on s1 and s2) can be expressed as functions of H_{X}, H_{Z}, α and β as below:

Hs1=H_{X} cos α+H_{Z} sin α (0<α<180) (1)

Hs1=H_{X} cos β+H_{Z} sin β (0<⊖<180,β≠α) (2)

Then, H_{X} and H_{Z} can be solved in terms of Hs1, Hs2, α and β:

$$\begin{matrix}{H}_{X} = \frac{\vert \begin{matrix}Hs 1 & sin α \\ Hs 2 & sin β\end{matrix} \vert}{\vert \begin{matrix}cos α & sin α \\ cos β & sin β\end{matrix} \vert} ; & ( 3 ) \\ {H}_{Z} = \frac{\vert \begin{matrix}cos α & Hs 1 \\ cos β & Hs 2\end{matrix} \vert}{\vert \begin{matrix}cos α & sin α \\ cos β & sin β\end{matrix} \vert} . & ( 4 )\end{matrix}$$

Similarly on the YZ plane, as shown in FIG. 4B, if s3 and s4 are two axes with angles γ and δ with respect to Y-axis, and if Hs3 and Hs4 represent the projections of H_{YZ} on axes s3 and s4 respectively, Hs3 and Hs4 can be expressed as:

Hs3=H_{Y} cos γ+H_{Z} sin γ (0<γ<180) (5)

Hs4=H_{Y} cos δ+H_{Z} sin δ (0<δ<180,δ≠γ) (6)

The solutions for H_{Y} and H_{Z} are:

$$\begin{matrix}{H}_{Y} = \frac{\vert \begin{matrix}H s 3 & sin γ \\ H s 4 & sin δ\end{matrix} \vert}{\vert \begin{matrix}cos γ & sin γ \\ cos δ & sin δ\end{matrix} \vert} , or & ( 7 ) \\ {H}_{Z} = \frac{\vert \begin{matrix}cos γ & Hs 3 \\ cos δ & Hs 4\end{matrix} \vert}{\vert \begin{matrix}cos γ & sin γ \\ cos δ & sin δ\end{matrix} \vert} , & ( 8 )\end{matrix}$$

where H_{Z} is a redundant solution that should have identical value to its solution in XZ plane.

Further, in the preferred embodiment, the interior angles of the four pyramid slopes with the base should be equal, i.e. α=180°−β and γ=180°−δ, so that the algebraic solutions for H_{X}, H_{Y} and H_{Z} can be simplified. Let the four axes aa′, bb′, cc′, and dd′ marked in FIG. 2A, FIG. 3A and FIG. 3B be s1, s2, s3, and s4, and the projections of H on aa′, bb′, cc′ are Ha, Hb, Hc and Hd, as illustrated in FIGS. 4A and 4B. Then solutions (1) and (2) are simplified to (9) and (10):

Ha=H_{X}·cos α+H_{Z}·sin α (0<α<90) (9)

Hb=−H_{X}·cos α+H_{Z}·sin α (0<α<90) (10)

Equation (3) and (4) becomes (11) and (12) in FIG. 4B:

Hc=H_{Y}·cos α+H_{Z}·sin α (0<α<90) (11)

Hd=−H_{Y} cos α+H_{Z}·sin α (0<α<90) (12)

The solution is the special case of the general solution expressed in equation (3), (4), (7) and (8):

H_{X}=(Ha−Hb)/2 cos α (13)

H_{Y}=(Hc−Hd)/2 cos α (14)

H_{Z}=(Ha+Hb)/2 sin α, or H_{Z}=(Hc+Hd)/2 sin α (15)

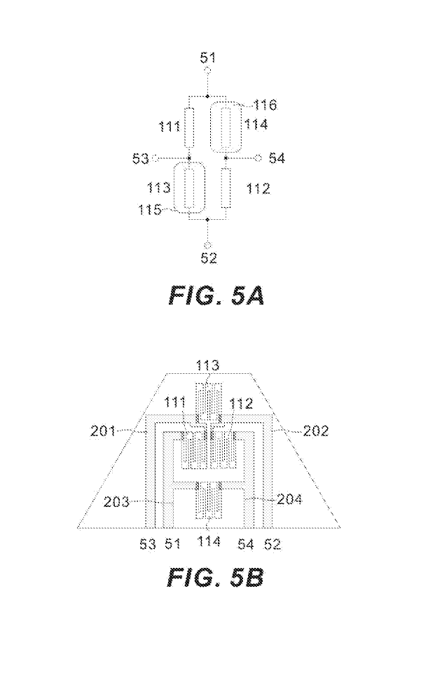

Referring now to production of the device in more detail, microfabrication is the preferred method to produce the device in quantities. A sensing unit can be singular or an plural of flux gates, Hall-effect devices, anisotropic magnetoresistive (AMR) resistors, giant magnetoresistive (GMR) resistors, or tunneling magnetoresistive (TMR) resistors, colossal magnetoresistive (CMR) resistors, tunnel magnetoresistance (TMR) devices, and inhomogeneity-induced magnetoresistance (IMR) devices. Although by using hybrid technology individual sensing units can be microfabricated, diced and attached on slopes of separately produced pyramids, it is preferred that the entire device is produced in monolithic form by using microfabrication processes that heavily employed to produce MEMS devices and ICs. An exemplary microfabrication process flow for producing the exemplary embodiments is presented below. The pyramids 11, 21, 31 and 32, or 41 and 42 on or in the silicon substrates are preferably produced by anisotropic etching out of bulk silicon wafers, IC or MEMS wafers. The microfabrication of aforementioned exemplary magnetoresistive thin film resistors and interconnections on the four slopes of the pyramids can employ photolithography, thin film deposition, and chemical vapor deposition. GMR resistive films are preferred. As shown FIG. 5A, on slope 110 for example, four GMR resistors 111, 112, 113 and 114 are configured as a full Wheatstone bridge. The resistance value of 112 and 113 changes in proportion to the change of magnetic field projected on their longitudinal directions. Shielded by the dual functional flux concentrators 115 and 116, the resistance of 113 and 114 remain constant and do not change with magnetic fields. The node 51, 52, 53 and 54 are the Wheatstone bridge terminals. Layouts of resistors on slopes 120, 130 and 140 are as same as on 110. An exemplary metal trace layout of this Wheatstone bridge circuit is shown in FIG. 5B, where 201, 202, 203, 204 are the four segments of non-ferromagnetic conductors interconnecting the four resistors. The metalization and passivation steps can share with MEMS or IC fabrication processes if MEMS or IC wafers are used as substrate. All four terminals 51, 52, 53 and 54 lead to the base of the pyramid for further circuit connections or packaging. Instead of a full Wheatstone bridge, a half-bridge with one active resistor and one shielded resistor, or a single active resistor may also be implemented as a sensing unit.

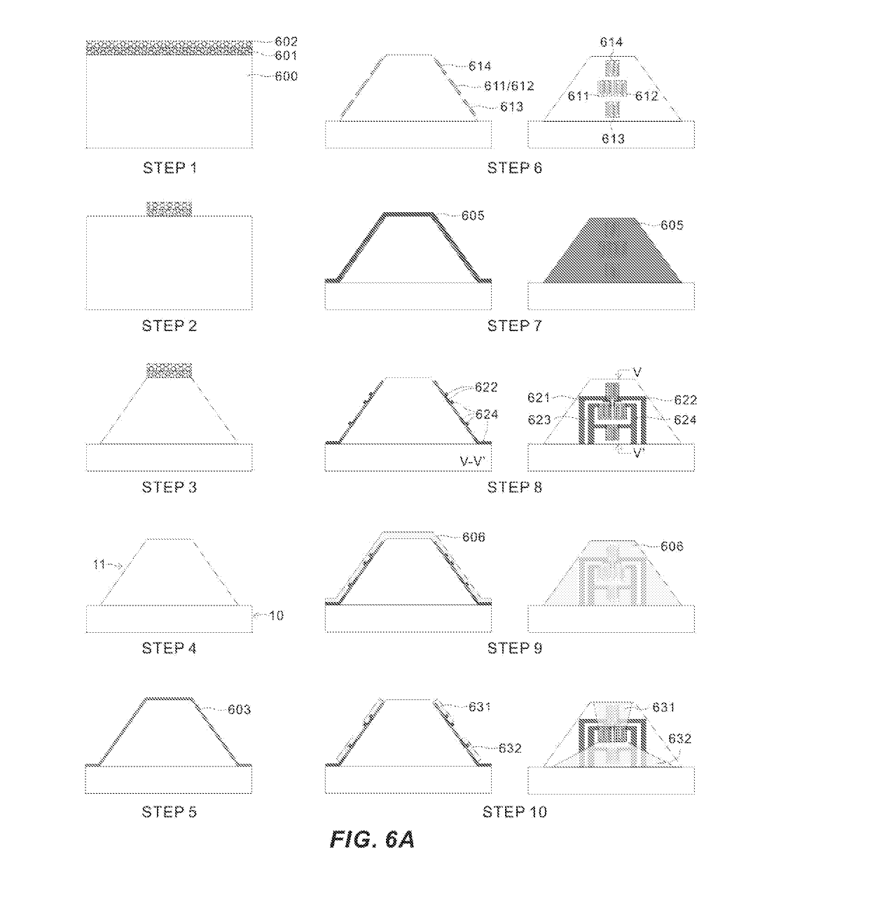

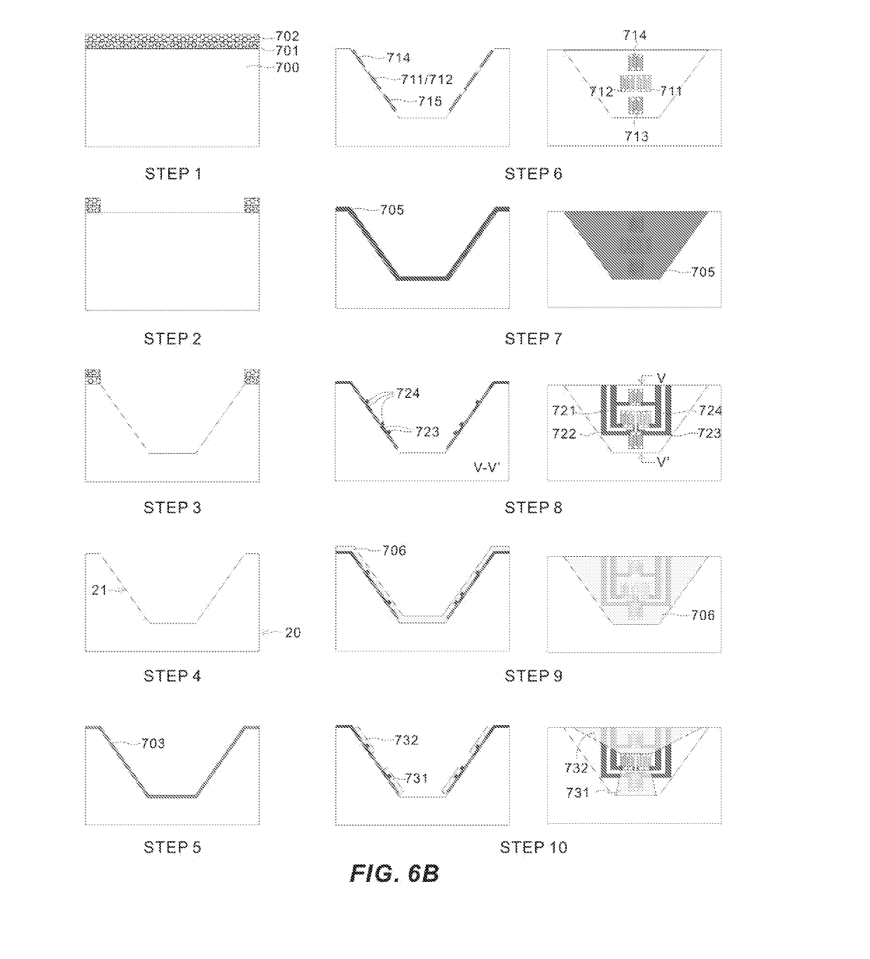

Further, FIG. 6A and FIG. 6B herein illustrate the preferred microfabrication process of the exemplary embodiments in more detail. The pyramid formation processes are similar for convex pyramids such as the first and the third exemplary embodiments presented in FIG. 1A and FIG. 1C respectively. For the first exemplary embodiment, a square pyramid with four identical slopes, each with some tilt angle, is created by wet etching of a <100> silicon wafer. For the third exemplary embodiment, a rectangular pyramid is used. Using the formation process of the first exemplary embodiment as an example, in Step 1, the <100> surface of the silicon wafer 600 is coated with a layer of silicon nitride thin film 601, followed by a layer of silicon oxide thin film 602. In Step 2, a predetermined hard mask, i.e. a square of the thin films, is formed at the location of the pyramid by photolithography and then etching off the rest of the films. In step 3, a square pyramid is created using etchants, for example, timed anisotropic etching with 20 wt % tetramethylammonium hydroxide (TMAH) between 70°-90° C., or alternatively, a combination of deep reactive ion etching (dry etching) and wet etching, to achieve a desired frustum height, for example, 200 micrometers. Step 1 to 3 concludes the preparation steps for the convex frustum. For the other convex embodiments, such as the third exemplary embodiment, a rectangular hard mask will be used to produce a rectangular pyramid. The processes are also used for concave pyramids such as the second or the fourth exemplary embodiments, except that in Step 2, the a hard mask exposes a window on the site of pyramid for etching, as shown in Step 2 of FIG. 6B. The rest of the processes are identical for all devices. Using the process for the first exemplary embodiment as an example, in Step 4, the four slope surfaces of the pyramid frustum 11 on substrate 10 are coated with a dielectric material, such as silicon dioxide, using thermal oxidation or chemical vapor deposition process. In Step 5, magnetoresistive film 603 is deposited on entire surface of the pyramid. In Step 6, 603 is patterned using photolithography and then etched to shape the resistors 611, 612, 613 and 614. Both cross-section and front views of the devices are illustrated from Step 6 to Step 10 of FIG. 6A and FIG. 6B. Step 7 deposits a non-ferromagnetic metal film 605 for resistor interconnections. Step 8 uses photolithography and selective etching to create conductive strips 621, 622, 623 and 624 to the pattern as shown in FIG. 5B. Alternatively, Step 7 and 8 can be replaced with a lift-off process. Step 9 deposits a dielectric layer (not shown in the figure) and a high permeability metal layer 606. Step 10 patterns 606 through photolithography and etching, and shapes 606 to flux concentrators 631 and 632, leaving the dielectric layer for protection. The final step is to expose the contacting pads to the terminals 51, 52, 53 and 54 by opening a window through the dielectric layer (not shown in the figure).

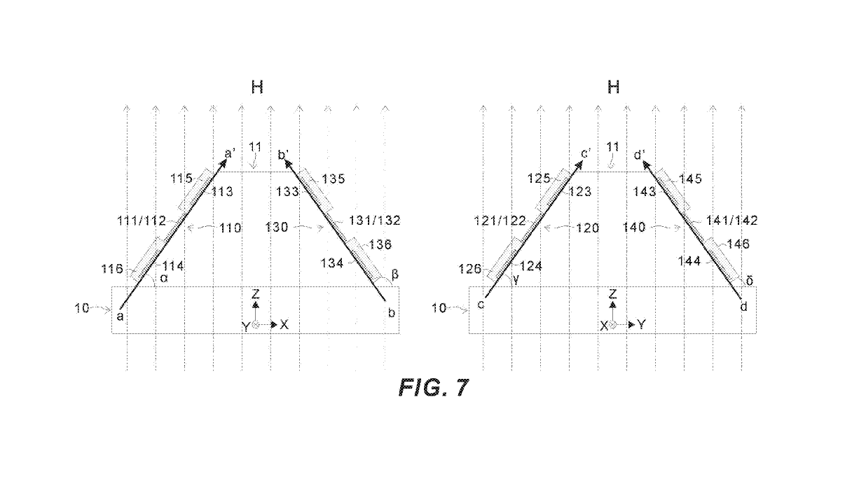

Referring now to the unique fabrication and testing methods of the aforementioned sensing units by taking advantage of their common sensitivity direction along the Z-axis. In order to render the sensing unit bipolar, during magnetoresistive film fabrication, a ferromagnetic pinning layer can be fabricated next to the magnetoresistive film. This pinning layer can then be magnetized to the desired polarity by applying an external field. Other magnetoresistive devices often need to be polarized by magnetizing each orthogonal direction separately. This invention instead allows biasing of all sensing units at the same time by magnetization along Z-axis only once to polarize the pinning layer, as shown in FIG. 7. In addition, testing of the device only requires applying a Z-axis field to characterize all the sensing units: of the preferred embodiment, they should have identical response if they are made the same. Also, characterization, and resetting of the device can also be performed by applying field of Z-axis only, allowing easy method to recover a device destroyed in an out-of-range strong field without replacing the device.

In addition, the advantages of the present invention include, without limitation, that when implemented by symmetrical square pyramid structure, the three sensitivity axes converge to a single point, which is ideal for mapping magnetic field in applications such as non-destructive evaluation or magnetic field probing using an atomic force microscope (AFM).

The invention should not be limited by the foregoing written description of embodiments, methods, and examples, but by all embodiments and methods within the scope and spirit of the invention.

What is claimed is:

1. A three-axis magnetic field sensing device, comprising:
a. in combination, at least one pyramid and means for providing a plurality of slope surfaces intercepting a reference plane with slope angles,
b. a plurality of field sensing apparatus disposed on a collection of said slope surfaces so that components of a magnetic field with respect to said slope angles can be measured,
whereby said magnetic field can be represented by a group of three mutually orthogonal vectors each in a mathematical expression in terms of measurement values of said field sensing apparatus and said predetermined slope angles.

2. The three-axis magnetic field sensing device of claim 1 wherein the pyramid is selected from:
a convex pyramid or a convex pyramid frustum above a substrate, or
a concave pyramid or a concave pyramid frustum in a substrate.

3. The three-axis magnetic field sensing device of claim 1 wherein the pyramid or pyramid frustum in claim 2 further comprises a minimum of 4 slopes that are not parallel to each other.

4. The three-axis magnetic field sensing device of claim 1 wherein the field sensing apparatuses comprise a magnet field sensing unit selected from the group consisting of: (i) Hall-effect devices, (ii) anisotropic magnetoresistive (AMR) resistors, (iii) giant magnetoresistive (GMR) resistors, (iv) colossal magnetoresistive (CMR) resistors, (v) tunnel magnetoresistance (TMR) devices, (vi) flux gates, and (vii) inhomogeneity-induced magnetoresistance (IMR) devices.

5. The three-axis magnetic field sensing device of claim 1 wherein a field sensing apparatus comprises an in-plane sensitivity axis, or an out-of-plane sensitivity axis of which the direction can be expressed with said slope angle of the plane where the sensing apparatus reside in.

6. The three-axis magnetic field sensing device of claim 1 wherein a first sensitivity axis of a first sensing apparatus is orthogonal to a second sensitivity axis of a second sensing apparatus.

7. The three-axis magnetic field sensing device of claim 1 wherein a third sensitivity axis of a third sensing apparatus is in plane of or parallel to the first sensitivity axis, a fourth sensitivity axis of a fourth sensing apparatus is in plane of or parallel to the second sensitivity axis.

8. A microfabrication method to produce the device of claim 1, the method comprising:
a. forming pyramid or pyramid frustum structure by wet etching said substrate to create said slope surfaces,
b. dispose magnetic field sensing apparatus on said slopes by thin film deposition, lithography and selective etching,
c. forming non-ferromagnetic conductive interconnecting strips,

9. A method of biasing all said magnetic field sensing apparatus of claim 1 at the same time with an external magnetic field by applying a magnetic field along a common axis that all sensing apparatuses have sensitivity on,
whereby all said magnetic field sensing apparatus can be polarize or depolarized, or
whereby individual said magnetic field sensing apparatus can be characterize.
